(19) United States
(12) Patent Application Publication
(10) Pub. No.: US 2014/0320216 A1
(43) Pub. Date: Oct. 30, 2014

(54) OSCILLATOR CIRCUIT

(71) Applicant: RICHTEK TECHNOLOGY CORP., Chupei City (TW)

(72) Inventor: Chih-Hsien WANG, Pingzhen City (TW)

(73) Assignee: RICHTEK TECHNOLOGY CORP., Chupei City (TW)

(21) Appl. No.: 14/022,547

(22) Filed: Sep. 10, 2013

(30) Foreign Application Priority Data
Apr. 25, 2013 (TW) 102207558

(51) Int. Cl. H03L 7/08

(52) U.S. Cl. CPC H03L 7/08
USPC 331/25

(57) ABSTRACT

An oscillator circuit includes: a switched-capacitor filter filtering a voltage at a common node between a current generating unit and a frequency-controlled resistor so as to generate a filtered voltage; an amplifier generating a control voltage based on the filtered voltage and a voltage at a common node between the current generating unit and a reference resistor; a voltage-controlled oscillator generating an oscillation signal based on the control voltage; and a control signal generating unit generating, based on the oscillation signal, a control input having a frequency proportional to that of the oscillation signal. The frequency-controlled resistor has a resistance variable according to the control input.

### CROSS-REFERENCE TO RELATED APPLICATION

This application claims priority of Taiwanese Application No. 102207558, filed on Apr. 25, 2013, the contents of which are hereby incorporated by reference.

### BACKGROUND OF THE INVENTION

1. Field of the Invention

This invention relates to an oscillator circuit, and more particularly to an oscillator circuit that uses a frequency-locked loop.

2. Description of the Related Art

Referring to FIG. 1, a conventional oscillator circuit using a frequency-locked loop disclosed in U.S. Pat. No. 5,994,967 is shown to include a current generating unit 11, two bipolar junction transistors 12, 13, a frequency-controlled resistor 14, a reference resistor 15, an amplifier 16, a low pass filter 17, a voltage-controlled oscillator 18, and a frequency divider 19.

It is noted that the low pass filter 17 coupled between an output terminal of the amplifier 16 and the voltage-controlled oscillator 18 is preferably an RC filter, which occupies a relatively large on-chip area, instead of a switched-capacitor filter, which occupies a relatively small on-chip area. This is because, if a switched-capacitor filter is adopted as the low pass filter 17, a filtered voltage generated by the low pass filter 17 may have an unwanted ripple component caused by switching operations of the low pass filter 17, thereby resulting in instability of a frequency of an oscillation signal, which is generated by the voltage-controlled oscillator 18 based on the filtered voltage. Therefore, the conventional oscillator circuit disadvantageously has a relatively large on-chip area.

Moreover, when a switched-capacitor acts as the frequency-controlled resistor 14, a voltage at a node 10 may change over a relatively large range. In this case, the current generating unit 11 may not operate properly.

### SUMMARY OF THE INVENTION

Therefore, an object of the present invention is to provide an oscillator circuit that has a relatively small on-chip area.

According to this invention, an oscillator circuit comprises a current generating unit, a frequency-controlled resistor, a switched-capacitor filter, a reference resistor, an amplifier, a voltage-controlled oscillator, and a control signal generating unit. The current generating unit outputs first and second currents. The frequency-controlled resistor is coupled to the current generating unit for receiving the first current therefrom. The switched-capacitor filter is coupled to a first common node between the current generating unit and the frequency-controlled resistor, and is operable to filter a voltage at the first common node so as to generate a filtered voltage. The reference resistor is coupled to the current generating unit for receiving the second current therefrom. The amplifier has a first input terminal coupled to the switched-capacitor filter for receiving the filtered voltage therefrom, a second input terminal coupled to a second common node between the current generating unit and the reference resistor, and an output terminal. The amplifier is operable to generate a control voltage based on the filtered voltage and a voltage at the second common node, and output the control voltage at the output terminal. The voltage-controlled oscillator is coupled to the output terminal of the amplifier for receiving the control voltage therefrom, and is operable to generate an oscillation signal based on the control voltage. The control signal generating unit is coupled to the voltage-controlled oscillator and the frequency-controlled resistor, and receives the oscillation signal from the voltage-controlled oscillator. The control signal generating unit is operable to generate, based on the oscillation signal, a control input having a frequency proportional to that of the oscillation signal, and output the control input to the frequency-controlled resistor such that the frequency-controlled resistor has a resistance variable according to the control input from the control signal generating unit.

### BRIEF DESCRIPTION OF THE DRAWINGS

Other features and advantages of the present invention will become apparent in the following detailed description of the preferred embodiment of this invention, with reference to the accompanying drawings, in which:

FIG. 1 is a schematic circuit block diagram illustrating a conventional oscillator circuit that uses a frequency-locked loop;

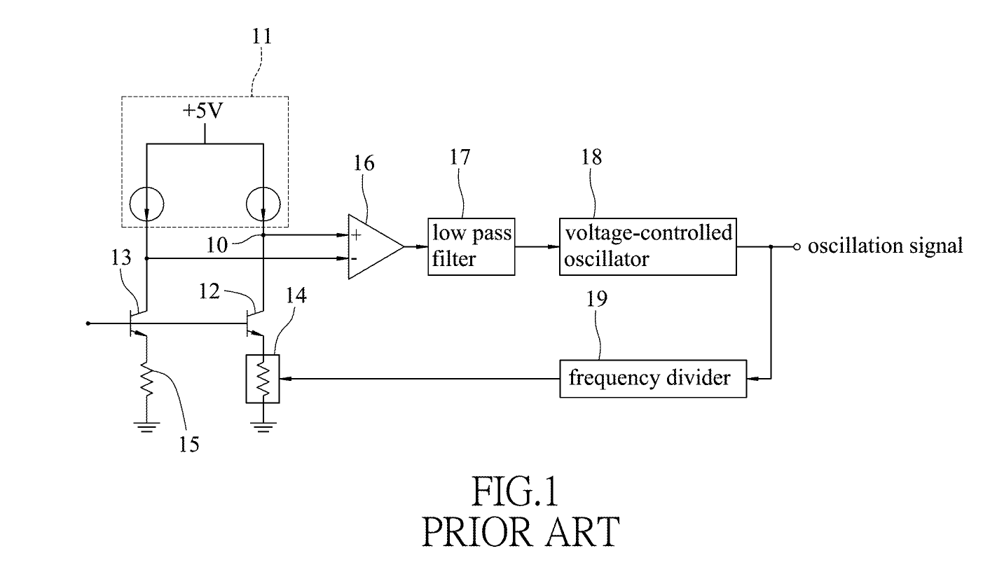

FIG. 2 is a schematic circuit block diagram illustrating the preferred embodiment of an oscillator circuit according to this invention; and

FIG. 3 is a schematic circuit diagram illustrating a frequency-controlled resistor and a switched-capacitor filter of the oscillator circuit of the preferred embodiment.

### DETAILED DESCRIPTION OF THE PREFERRED EMBODIMENT

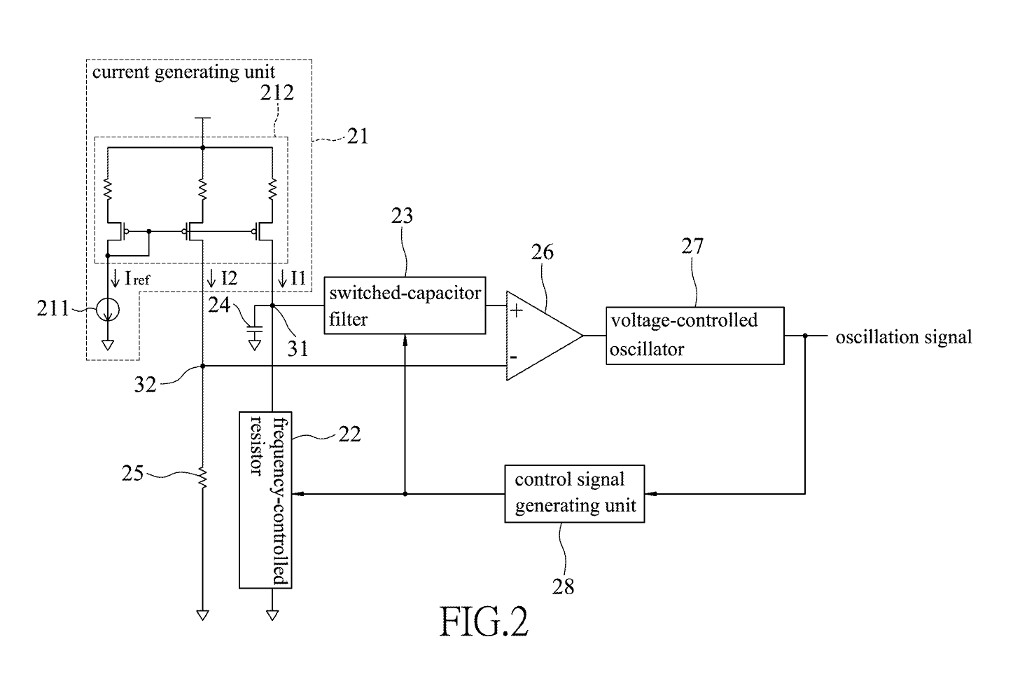

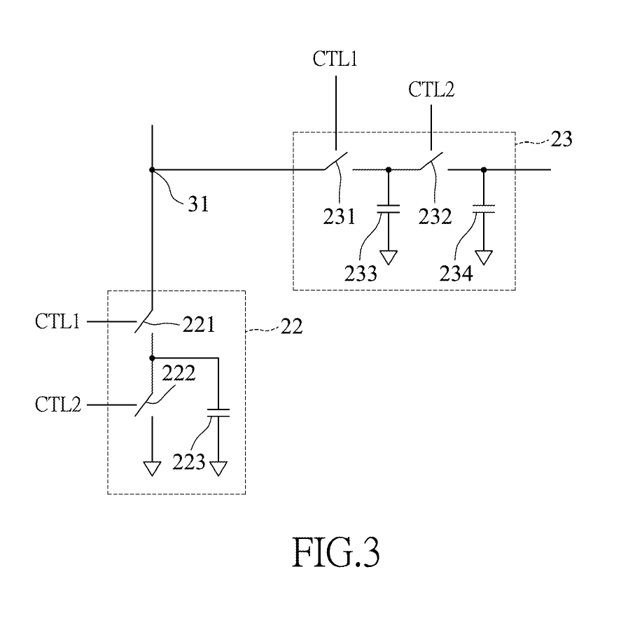

Referring to FIGS. 2 and 3, the preferred embodiment of an oscillator circuit according to this invention is shown to use a frequency-locked loop, and includes a current generating unit 21, a frequency-controlled resistor 22, a switched-capacitor filter 23, a capacitor 24, a reference resistor 25, an amplifier 26, a voltage-controlled oscillator 27, and a control signal generating unit 28.

The current generating unit 21 outputs first and second currents (I1, I2). In this embodiment, the current generating unit 21 includes a current source 211 and a source-degenerated current mirror 212. The current source 211 supplies a reference current (Iref). The source-degenerated current mirror 212 is coupled to the current source 211 for receiving the reference current (Iref), and is operable to generate the first and second currents (I1, I2) based on the reference current (Iref). It is noted that the source-degenerated current mirror 212 can ensure that each of the first and second currents (I1, I2) follows the reference current (Iref) with relatively high precision.

The frequency-controlled resistor 22 has a resistance variable according to a control input. The frequency-controlled resistor 22 is coupled between the source-degenerated current mirror 212 of the current generating unit 21 and ground, and receives the first current (I1) from the source-degenerated current mirror 212 such that a voltage at a first common node 31 between the source-degenerated current mirror 212 and the frequency-controlled resistor 22 is equal to a product of the first current (I1) and the resistance of the frequency-controlled resistor 22. In this embodiment, the control input includes complementary first and second control signals (CTL1, CTL2), and the frequency-controlled resistor 22 is in the form of a switched-capacitor. The frequency-controlled resistor 22 includes two switches 221, 222 operable respectively in response to the first and second control signals (CTL1, CTL2), and a capacitor 223. The switches 221, 222 are coupled between the first common node 31 and ground in series with the switch 221 coupled to the first common node 31 and the switch 222 coupled to ground. The capacitor 223 is coupled to the switch 222 in parallel.

The switched-capacitor filter 23 is coupled to the first common node 31, and has a cut-off frequency that varies according to the control input. The switched-capacitor filter 23 is operable to filter the voltage at the first common node 31 so as to generate a filtered voltage. In this embodiment, the switched-capacitor filter 23 includes two switches 231, 232 operable respectively in response to the first and second control signals (CTL1, CTL2), and two capacitors 233, 234. The switch 231 and the capacitor 233 are coupled between the first common node 31 and ground in series with the switch 231 coupled to the first common node 31 and the capacitor 233 coupled to ground. The switch 232 and the capacitor 234 are coupled in series. The series connection of the switch 232 and the capacitor 234 is coupled to the capacitor 233 in parallel. The switched-capacitor filter 23 outputs the filtered voltage at a common node between the switch 232 and the capacitor 234.

The capacitor 24 is coupled between the first common node 31 and ground for stabilizing the voltage at the first common node 31 to thereby ensure proper operation of the source-degenerated current mirror 212 of the current generating unit 21.

The reference resistor 25 is coupled between the source-degenerated current mirror 212 of the current generating unit 21 and ground, and receives the second current (I2) from the source-degenerated current mirror 212 such that a voltage at a second common node 32 between the source-degenerated current mirror 212 and the reference resistor 25 is equal to a product of the second current (I2) and a resistance of the reference resistor 25.

The amplifier 26 has a non-inverting input terminal serving as a first input terminal and coupled to the switched-capacitor filter 23 for receiving the filtered voltage therefrom, an inverting input terminal serving as a second input terminal and coupled to the second common node 32, and an output terminal. The amplifier 26 is operable to generate a control voltage based on the filtered voltage and the voltage at the second common node 32, and output the control voltage at the output terminal.

The voltage-controlled oscillator 27 is coupled to the output terminal of the amplifier 26 for receiving the control voltage therefrom, and is operable to generate an oscillation signal based on the control voltage.

The control signal generating unit 28 is coupled to the voltage-controlled oscillator 27, the frequency-controlled resistor 22 and the switched-capacitor filter 23, and receives the oscillation signal from the voltage-controlled oscillator 27. The control signal generating unit 28 is operable to generate, based on the oscillation signal, the control input having a frequency proportional to that of the oscillation signal, and output the control input to each of the frequency-controlled resistor 22 and the switched-capacitor filter 23.

In this embodiment, the frequency of the oscillation signal indicated by Fosc can be expressed by the following equation:

$$Fosc = \frac{I 1 \cdot N}{I 2 \cdot R 25 \cdot C 223} ,$$

where N is a ratio of the frequency (Fosc) to the frequency of the control input, R25 is the resistance of the reference resistor 25, and C223 is a capacitance of the capacitor 223 of the frequency-controlled resistor 22.

In this embodiment, the cut-off frequency of the switched-capacitor filter 23 indicated by Fcut-off can be expressed by the following equation:

$$Fcut \text{-} off = \frac{C 233 \cdot Fosc}{C 234 \cdot N} ,$$

where C233 and C234 are capacitances of the capacitors 233, 234 of the switched-capacitor filter 23, respectively.

It is noted that, in other embodiments, the frequency-controlled resistor 22 and the reference resistor 25 can be coupled to a power source (not shown), instead of ground, such that the voltage at the first common node 31 is equal to a voltage supplied by the power source minus the product of the first current (I1) and the resistance of the frequency-controlled resistor 22, and that the voltage at the second common node 32 is equal to the voltage supplied by the power source minus the product of the second current (I2) and the resistance of the reference resistor 25. In this case, the inverting input terminal of the amplifier 26 serves as the first input terminal and is coupled to the switched-capacitor filter 23, and the non-inverting input terminal of the amplifier 26 serves as the second input terminal and is coupled to the second common node 32.

In view of the above, the switched-capacitor filter 23 is coupled to the first input terminal (i.e., the non-inverting input terminal for the preferred embodiment) of the amplifier 26, and the amplifier 26 has an inherent low pass filtering property. Therefore, even if the filtered voltage generated by the switched-capacitor filter 23 has a ripple component caused by operations of the switches 231, 232 of the switched-capacitor filter 23, the ripple component of the filtered voltage will be removed using the low pass filtering property of the amplifier 26, thereby ensuring that the frequency of the oscillation signal generated by the voltage-controlled oscillator 27 is not affected by the ripple component of the filtered voltage. Due to the presence of the switched-capacitor filter 23, which occupies a relatively small on-chip area, the oscillator circuit of this embodiment occupies a decreased overall on-chip area.

While the present invention has been described in connection with what is considered the most practical and preferred embodiment, it is understood that this invention is not limited to the disclosed embodiment but is intended to cover various arrangements included within the spirit and scope of the broadest interpretation and equivalent arrangements.

What is claimed is:

1. An oscillator circuit comprising:
a current generating unit for outputting first and second currents;
a frequency-controlled resistor coupled to said current generating unit for receiving the first current therefrom;
a switched-capacitor filter coupled to a first common node between said current generating unit and said frequency-controlled resistor, and operable to filter a voltage at said first common node so as to generate a filtered voltage;
a reference resistor coupled to said current generating unit for receiving the second current therefrom;
an amplifier having a first input terminal coupled to said switched-capacitor filter for receiving the filtered voltage therefrom, a second input terminal coupled to a second common node between said current generating unit and said reference resistor, and an output terminal, said amplifier being operable to generate a control voltage based on the filtered voltage and a voltage at said second common node, and output the control voltage at said output terminal;
a voltage-controlled oscillator coupled to said output terminal of said amplifier for receiving the control voltage therefrom, and operable to generate an oscillation signal based on the control voltage; and
a control signal generating unit coupled to said voltage-controlled oscillator and said frequency-controlled resistor, and receiving the oscillation signal from said voltage-controlled oscillator, said control signal generating unit being operable to generate, based on the oscillation signal, a control input having a frequency proportional to that of the oscillation signal, and output the control input to said frequency-controlled resistor such that said frequency-controlled resistor has a resistance variable according to the control input.

2. The oscillator circuit of claim 1, wherein said frequency-controlled resistor is coupled between said first common node and ground, said reference resistor being coupled between said second common node and ground, said first input terminal of said amplifier being a non-inverting input terminal, said second input terminal of said amplifier being an inverting input terminal.

3. The oscillator circuit of claim 1, further comprising a capacitor coupled between said first common node and ground.

4. The oscillator circuit of claim 1, wherein said current generating unit includes a source-degenerated current mirror that generates the first and second currents.
